(19) United States
(12) Patent Application Publication
(10) Pub. No.: US 2025/0155819 A1
(43) Pub. Date: May 15, 2025

(54) PROFILE DISPLAY DEVICE, LASER DEVICE, AND ELECTRONIC DEVICE MANUFACTURING METHOD

(71) Applicant: Gigaphoton Inc., Tochigi (JP)

(72) Inventors: Yutaka IGARASHI, Oyama-shi (JP); Akihiko MARUMO, Oyama-shi (JP)

(73) Assignee: Gigaphoton Inc., Tochigi (JP)

(21) Appl. No.: 18/913,610

(22) Filed: Oct. 11, 2024

(30) Foreign Application Priority Data
Nov. 15, 2023 (JP) 2023-194221

(51) Int. Cl. G03F 7/00; G06T 3/20; G06T 11/20; H01S 3/00; H01S 3/034; H01S 3/136

(52) U.S. Cl. CPC G03F 7/70025; G03F 7/70041; G06T 3/20; G06T 11/203; H01S 3/0014; H01S 3/034; H01S 3/136

(57) ABSTRACT

A profile display device includes an interface configured to receive a beam profile of laser light, a processor configured to generate a shifted outline by shifting a position of an outline of the beam profile in accordance with deviation of a light intensity distribution in the beam profile, and a display configured to display the beam profile and the shifted outline.

### CROSS-REFERENCE TO RELATED APPLICATIONS

The present application claims the benefit of Japanese Patent Application No. 2023-194221, filed on Nov. 15, 2023, the entire contents of which are hereby incorporated by reference.

### BACKGROUND

### 1. Technical Field

The present disclosure relates to a profile display device, a laser device, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectral line width of about 350 to 400 μm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be narrowed to the extent that the chromatic aberration can be ignored. For this purpose, there is a case in which a line narrowing module (LNM) including a line narrowing element (etalon, grating, and the like) is provided in a laser resonator of the gas laser device to narrow a spectral line width. A gas laser device with a narrowed spectral line width is referred to as a line narrowing gas laser device.

### LIST OF DOCUMENTS

### Patent Documents

Patent Document 1: US Patent Application Publication No. 2014/348188

### SUMMARY

A profile display device according to an aspect of the present disclosure includes an interface configured to receive a beam profile of laser light, a processor configured to generate a shifted outline by shifting a position of an outline of the beam profile in accordance with deviation of a light intensity distribution in the beam profile, and a display configured to display the beam profile and the shifted outline.

A laser device according to an aspect of the present disclosure includes a laser oscillator configured to output laser light, a beam profiler configured to acquire a beam profile of the laser light, a processor configured to generate a shifted outline by shifting a position of an outline of the beam profile in accordance with deviation of a light intensity distribution in the beam profile, and a display configured to display the beam profile and the shifted outline.

An electronic device manufacturing method according to an aspect of the present disclosure includes generating laser light using a laser device, outputting the laser light to an exposure a apparatus, and exposing photosensitive substrate to the laser light in the exposure apparatus to manufacture an electronic device. Here, the laser device includes a laser oscillator configured to output the laser light, a beam profiler configured to acquire a beam profile of the laser light, a processor configured to generate a shifted outline by shifting a position of an outline of the beam profile in accordance with deviation of a light intensity distribution in the beam profile, and a display configured to display the beam profile and the shifted outline.

### BRIEF DESCRIPTION OF THE DRAWINGS

Embodiments of the present disclosure will be described below merely as examples with reference to the accompanying drawings.

FIG. 1 shows the configuration of an exposure system in a comparative example.

FIG. 2 shows the configuration of a laser device according to the comparative example.

FIG. 3 is a flowchart showing operation of a profile display device according to an embodiment.

FIG. 4 is a flowchart showing an example of processing of calculating the centroid and the center of a beam profile and generating an outline of the beam profile.

FIG. 5 shows an example of the beam profile and the centroid thereof.

FIG. 6 is a graph showing an example of a distribution of a light intensity along a straight line in an X direction passing through the centroid position in FIG. 5.

FIG. 7 is a graph showing an example of a distribution of the light intensity along a straight line in a Y direction passing through the centroid position in FIG. 5.

FIG. 8 shows an example of an outline defined by X1, X2, Y1, and Y2 obtained in FIGS. 6 and 7.

FIG. 9 is flowchart a showing an example of processing of generating a shifted outline.

FIG. 10 shows the shifted outline generated by shifting the position of the outline in accordance with a shift of the centroid with respect to the center of the beam profile.

FIG. 11 is a flowchart showing an example of processing of starting displaying of the beam profile and the shifted outline.

FIG. 12 shows a display example of the beam profile and the shifted outline.

### DESCRIPTION OF EMBODIMENTS

### Contents

1. Comparative Example
   1.1 Configuration of Exposure Apparatus 200
   1.2 Operation of Exposure Apparatus 200
   1.3 Configuration of Laser Device 100
   1.4 Operation of Laser Device 100
   1.5 Problem of Comparative Example
2. Profile Display Device 34 which Displays Shifted Outline 51
   2.1. Overview
   2.2 Calculation of Centroid, Center, and Outline 50
   2.3 Calculation of Shifted Outline 51
   2.4 Displaying of Beam Profile and Shifted Outline 51
   2.5 Effect
3. Others

Hereinafter, an embodiment of the present disclosure will be described in detail with reference to the drawings. The embodiment described below show examples of the present disclosure and do not limit the contents of the present disclosure. Also, all configurations and operation described in the embodiment are not necessarily essential as configurations and operation of the present disclosure. Here, the same components are denoted by the same reference numeral, and duplicate description thereof is omitted.

### 1. Comparative Example

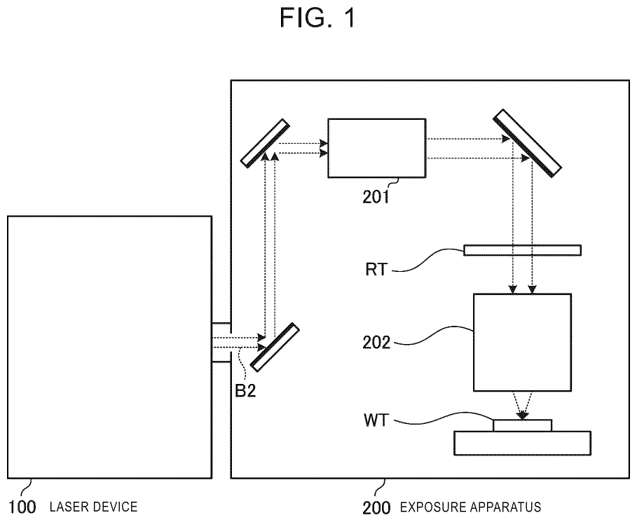

FIG. 1 shows the configuration of an exposure system in a comparative example. The comparative example of the present disclosure is an example recognized by the applicant as known only by the applicant, and is not a publicly known example admitted by the applicant.

The exposure system includes a laser device 100 and an exposure apparatus 200. The laser device 100 is configured to output laser light B2 toward the exposure apparatus 200.

### 1.1 Configuration of Exposure Apparatus 200

The exposure apparatus 200 includes an illumination optical system 201 and a projection optical system 202. The illumination optical system 201 illuminates a reticle pattern of a reticle (not shown) arranged on a reticle stage RT with the laser light B2 incident from the laser device 100. The projection optical system 202 causes the laser light B2 transmitted through the reticle to be imaged as being reduced and projected on a workpiece (not shown) arranged on a workpiece table WT. The workpiece is a photosensitive substrate such as a semiconductor wafer on which a resist film is applied.

### 1.2 Operation of Exposure Apparatus 200

The exposure apparatus 200 synchronously translates the reticle stage RT and the workpiece table WT in directions opposite to each other. Thus, the workpiece is exposed to the laser light B2 reflecting the reticle pattern. Through the exposure process as described above, the reticle pattern is transferred onto the semiconductor wafer. Thereafter, an electronic device can be manufactured through a plurality of processes.

### 1.3 Configuration of Laser Device 100

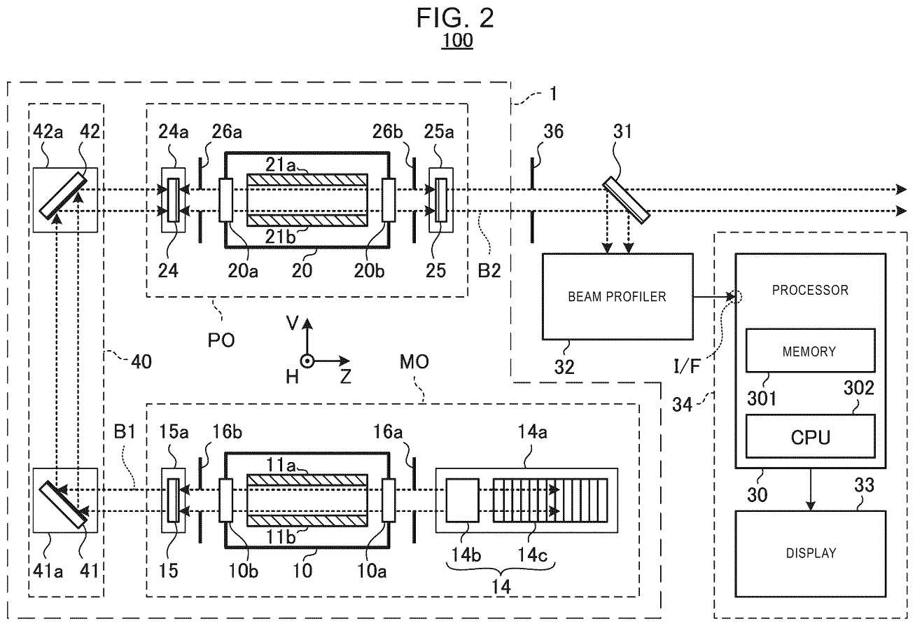

FIG. 2 shows the configuration of the laser device 100 according to the comparative example. The laser device 100 includes a laser oscillator 1, a beam profiler 32, and a profile display device 34. The laser oscillator 1 includes a master oscillator MO, a beam steering unit 40, and a power oscillator PO.

The master oscillator MO includes a laser chamber 10, a pair of discharge electrodes 11a, 11b, a line narrowing module 14, an output coupling mirror 15, slits 16a, 16b, and a pulse power source (not shown).

The line narrowing module 14 and the output coupling mirror 15 configure a laser resonator. The laser chamber 10 is arranged on the optical path of the laser resonator. Windows 10a, 10b are arranged at both ends of the laser chamber 10. The discharge electrodes 11a, 11b are arranged inside the laser chamber 10. The pulse power source is connected to the discharge electrode 11a. The laser chamber 10 is filled with a laser gas containing, for example, an argon gas or a krypton gas as a rare gas, a fluorine gas as a halogen gas, a neon gas as a buffer gas, and the like.

The line narrowing module 14 includes a prism 14b and a grating 14c. The prism 14b is arranged on the optical path of light output from the window 10a. The grating 14c is arranged on the optical path of the light having transmitted through the prism 14b. The posture of the line narrowing module 14 can be changed by an optical axis adjustment mechanism 14a.

The output coupling mirror 15 is a partial reflection mirror, and is arranged on the optical path of light output from the window 10b. The posture of the output coupling mirror 15 can be changed by an optical axis adjustment mechanism 15a.

The beam steering unit 40 includes high reflection mirrors 41, 42. The high reflection mirrors 41, 42 are arranged on the optical path of laser light B1 output from the master oscillator MO. The postures of the high reflection mirrors 41, 42 can be changed by optical axis adjustment mechanisms 41a, 42a, respectively.

The power oscillator PO is arranged on the optical path of the laser light B1 having passed through the beam steering unit 40. The power oscillator PO includes a laser chamber 20, a pair of discharge electrodes 21a, 21b, a rear mirror 24, an output coupling mirror 25, slits 26a, 26b, and a pulse power source (not shown).

Each of the rear mirror 24 and the output coupling mirror 25 is a partial reflection mirror. The postures of the rear mirror 24 and the output coupling mirror 25 can be changed by optical axis adjustment mechanisms 24a, 25a, respectively. The reflectance of the rear mirror 24 is set higher than the reflectance of the output coupling mirror 25. The rear mirror 24 and the output coupling mirror 25 configure a laser resonator. The laser chamber 20 is arranged on the optical path of the laser resonator. Windows 20a, 20b are arranged at both ends of the laser chamber 20.

In other respects, the above-described components of the power oscillator PO are similar to the corresponding components of the master oscillator MO.

The discharge directions between the discharge electrodes 11a, 11b and between the discharge electrodes 21a, 21b are represented by a V direction or a −V direction. The output direction of the laser light B1 from the output coupling mirror 15 is represented by a −Z direction, and the output direction of the laser light B2 from the output coupling mirror 25 is represented by a Z direction. The V direction and the Z direction are perpendicular to each other, and the direction perpendicular to both of them is represented by an H direction and a −H direction. Since the distances in the V direction between the discharge electrodes 11a, 11b and between the discharge electrodes 21a, 21b are longer than the widths in the H direction of the discharge electrodes 11a, 11b and of the discharge electrodes 21a, 21b, the beam cross section of the laser light B2 has a rectangular shape longer in the V direction than in the H direction.

Each of the optical axis adjustment mechanisms 14a, 15a, 24a, 25a, 41a, 42a includes, for example, a first adjustment shaft (not shown) that rotates about an axis parallel to the V direction and a second adjustment shaft (not shown) that rotates about an axis parallel to the H direction. The first and second adjustment shafts are adjusted by hand with first and second screws (not shown), respectively. Alternatively, the first and second adjustment shafts may be adjusted by first and second actuators (not shown), respectively. Each of the line narrowing module 14, the rear mirror 24, the output coupling mirrors 15, 25, and the high reflection mirrors 41, 42 corresponds to the optical element in the present disclosure. Each of the optical axis adjustment mechanisms 14a, 15a, 24a, 25a, 41a, 42a can be operated in parallel with the output of the laser light B1, B2.

A slit 36 and a beam splitter 31 are arranged on the optical path of the laser light B2 output from the power oscillator PO. The beam profiler 32 is arranged on the optical path of the laser light B2 having passed through the slit 36 and reflected by the beam splitter 31. The beam profiler 32 includes, for example, a transfer optical system (not shown) and an image sensor (not shown).

The profile display device 34 includes a processor 30 and a display 33. The processor 30 is a processing device including an interface I/F which receives data of a beam profile output from the beam profiler 32, a memory 301 in which a control program is stored, and a central processing unit (CPU) 302 which executes the control program. The processor 30 is specifically configured or programmed to perform various processes included in the present disclosure. The display 33 may be, for example, a liquid crystal display, an LED display, or a projector that projects an image on a screen.

### 1.4 Operation of Laser Device 100

When the pulse power source included in the master oscillator MO generates a high voltage pulse and the high voltage pulse is applied to the discharge electrode 11a, discharge occurs inside the laser chamber 10. The laser medium in the laser chamber 10 is excited by the energy of the discharge and shifts to a high energy level. When the excited laser medium then shifts to a low energy level, light having a wavelength corresponding to the difference between the energy levels is emitted. The light generated in the laser chamber 10 is output to the outside of the laser chamber 10 through the windows 10a, 10b.

The beam width of the light output through the window 10a of the laser chamber 10 is expanded by the prism 14b, and then the light is incident on the grating 14c. The light incident on the grating 14c from the prism 14b is reflected by a plurality of grooves of the grating 14c and is diffracted in a direction corresponding to the wavelength of the light. The prism 14b reduces the beam width of the diffracted light from the grating 14c and returns the light to the laser chamber 10 through the window 10a.

The output coupling mirror 15 transmits and outputs a part of the light output through the window 10b of the laser chamber 10, and reflects the other part back into the laser chamber 10 through the window 10b.

In this way, the light output from the laser chamber 10 reciprocates between the line narrowing module 14 and the output coupling mirror 15, and is amplified each time the light passes through the discharge space in the laser chamber 10. The light is line narrowed each time being turned back in the line narrowing module 14. The slits 16a, 16b block the end parts in the beam cross section where the beam quality is poor. In this way, the light having undergone laser oscillation and line narrowing is output as the laser light B1 from the output coupling mirror 15.

The beam steering unit 40 guides the laser light B1 to the power oscillator PO so that the laser light B1 output from the master oscillator MO enters the laser chamber 20 via the rear mirror 24.

The pulse power source included in the power oscillator PO generates a high voltage pulse, and the pulse high voltage is applied to the discharge electrode 21a. The operation timing of the pulse power source included in each of the master oscillator MO and the power oscillator PO is set so that the timing at which the laser light B1 output from the master oscillator MO enters the laser chamber 20 and the timing at which discharge occurs inside the laser chamber 20 are synchronized with each other.

The laser light B1 reciprocates between the rear mirror 24 and the output coupling mirror 25, and is amplified each time the laser light B1 passes through the discharge space in the laser chamber 20. The slits 26a, 26b block the end parts in the beam cross section where the beam quality is poor. The amplified laser light B2 is output from the output coupling mirror 25.

The slit 36 blocks the end parts in the beam cross section of the laser light B2 where the beam quality is poor. The beam splitter 31 transmits a part of the laser light B2 at high transmittance, and reflects the other part to enter the beam profiler 32. The beam profiler 32 acquires a beam profile of the laser light B2 and outputs data of the beam profile to the processor 30. The processor 30 causes the display 33 to display an image of the beam profile. Further, by reading the data of the beam profile into spreadsheet software, it is possible to calculate the difference between the position of the center and the position of the centroid of the beam cross section.

A person in charge of maintenance of the laser device 100 performs adjustment with the optical axis adjustment mechanisms 14a, 15a, 24a, 25a, 41a, 42a, and the like as much as possible based on the image of the beam profile, and then confirms the difference between the position of the center and the position of the centroid of the beam cross section calculated by the spreadsheet software to perform a final determination of adjustment completion. When the difference between the position of the center and the position of the centroid of the beam cross section is not within a specific range, adjustment is performed again.

### 1.5 Problem of Comparative Example

In the comparative example, the adjustment with the optical axis adjustment mechanisms 14a, 15a, 24a, 25a, 41a, 42a, and the like is performed based on the image of the beam profile. However, there is a limit in the adjustment through visual observation, and final confirmation is required to be made through the calculation result of the spreadsheet software. In order to confirm using the spreadsheet software, it is necessary to read data of the beam profile into the spreadsheet software, so that it takes time for adjustment.

### 2. Profile Display Device 34 which Displays Shifted Outline 51

### 2.1. Overview

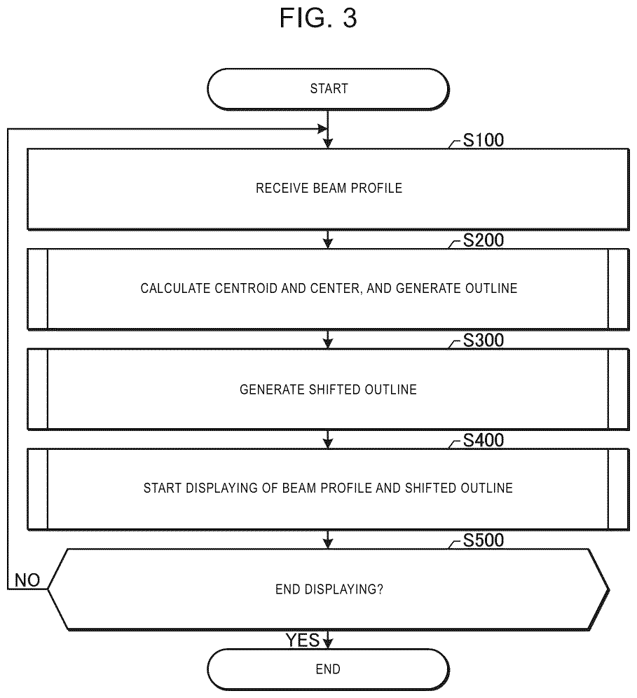

FIG. 3 is a flowchart showing operation of the profile display device 34 according to an embodiment. The configurations of the laser device 100 and the profile display device 34 of the embodiment are similar to those of the comparative example. The processor 30 included in the profile display device 34 performs the following processes to display the beam profile on the display 33.

In S100, the processor 30 receives the beam profile of the laser light B2 from the beam profiler 32. The reception of the beam profile is performed via the interface I/F.

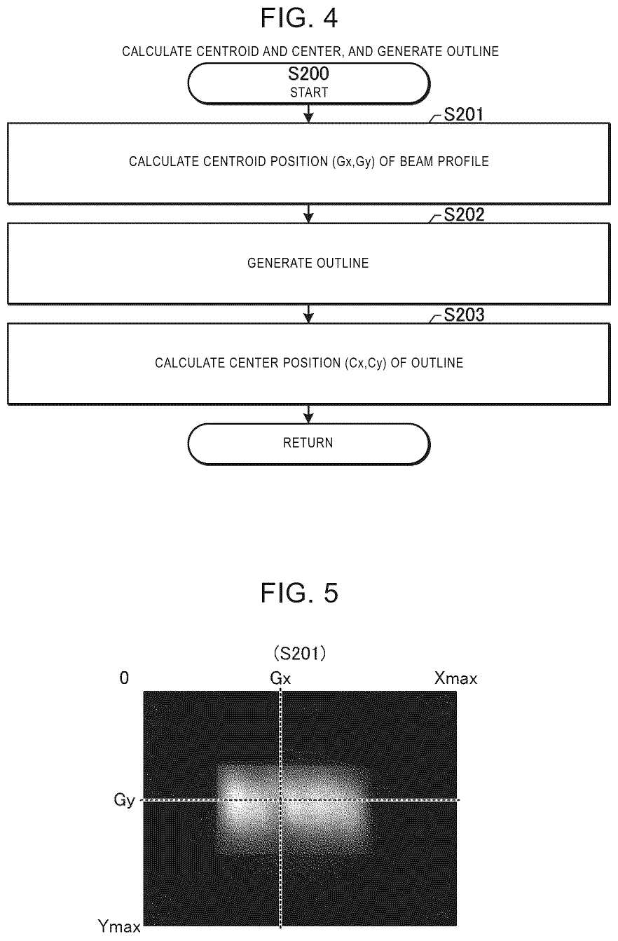

In S200, the processor 30 calculates the centroid and the center of the beam profile and generates an outline 50 of the beam profile. The difference between the centroid and the center of the beam profile is an example of the deviation of a light intensity distribution. The process of S200 and an example of the outline 50 will be described with reference to FIGS. 4 to 8.

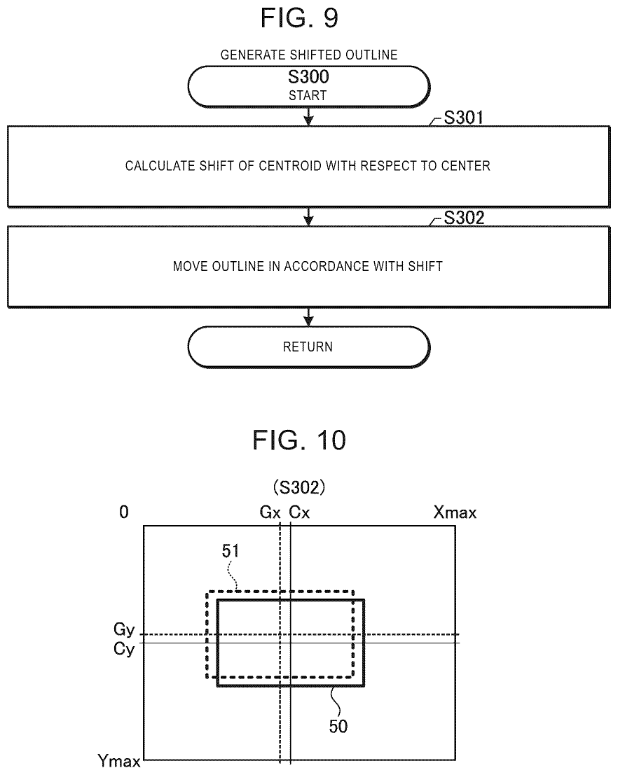

In S300, the processor 30 generates a shifted outline 51 by shifting the position of the outline 50 of the beam profile in accordance with the deviation of the light intensity distribution in the beam profile. The process of S300 and an example of the shifted outline 51 will be described with reference to FIGS. 9 and 10.

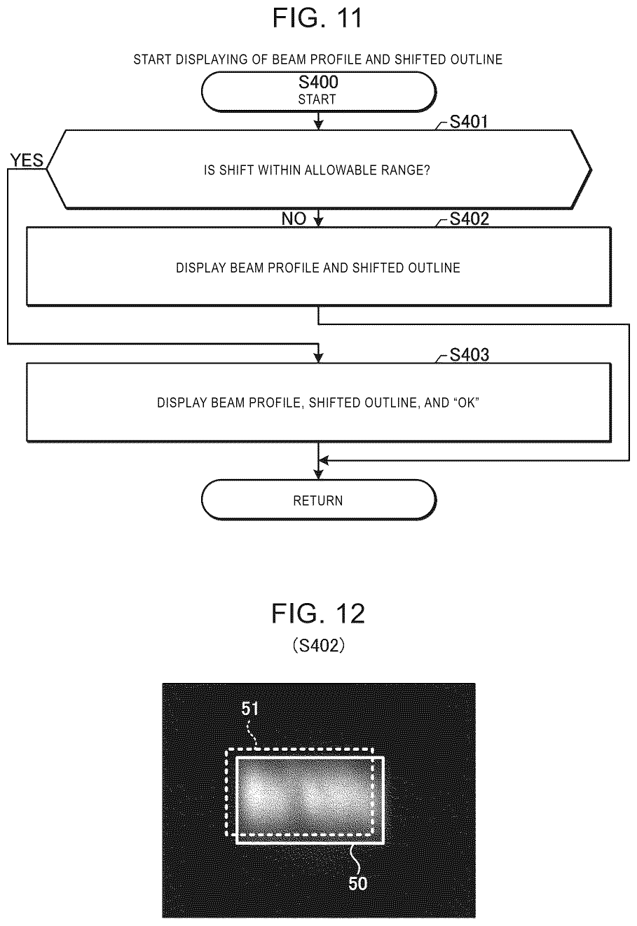

In S400, the processor 30 starts displaying the beam profile received in S100 and the shifted outline 51 generated in S300. An example of the process of S400 will be described with reference to FIGS. 11 and 12.

In S500, the processor 30 determines whether or not to end displaying the beam profile and the shifted outline 51. For example, when the person in charge of maintenance instructs to end displaying, it is determined that the displaying is ended. When the displaying is ended (S500: YES), the processor 30 ends processing of the present flowchart.

When the displaying is not ended (S500: NO), the processor 30 returns processing to S100. Accordingly, when the displaying is not ended, a new shifted outline 51 is generated at regular intervals (S300) based on a newly received beam profile (S100), and the display of the beam profile and the shifted outline 51 is updated every time a new shifted outline 51 is generated (S400). Accordingly, when the beam profile is changed by operating the optical axis adjustment mechanisms 14a, 15a, 24a, 25a, 41a, 42a, and the like, the display of the beam profile and the shifted outline 51 is updated in real time.

### 2.2 Calculation of Centroid, Center, and Outline 50

FIG. 4 is a flowchart showing an example of processing of calculating the centroid and the center of the beam profile and generating the outline 50 of the beam profile. The processing shown in FIG. 4 corresponds to a subroutine of S200 shown in FIG. 3.

In S201, the processor 30 calculates a centroid position (Gx, Gy) of the beam profile.

FIG. 5 shows an example of the beam profile and the centroid thereof. The beam profile is represented by a two-dimensional light intensity distribution in the beam cross section. The X coordinate and the Y coordinate are defined with the horizontal direction in FIG. 5 being the X direction and the vertical direction being the Y direction. The X direction in the beam profile corresponds to the V direction in the beam cross section of the laser light B2, and the Y direction in the beam profile corresponds to the H direction in the beam cross section of the laser light B2. The minimum value of the X coordinate is 0 and the maximum value thereof is Xmax, and the minimum value of the Y coordinate is 0 and the maximum value thereof is Ymax. The centroid position (Gx, Gy) of the beam profile can be calculated by following expressions, where I(X, Y) is the light intensity at a point (X, Y).

Gx=Σ(I(X,Y)×X)/Σ(I(X,Y))

Gy=Σ(I(X,Y)×Y)/Σ(I(X,Y))

Here, Σ(A) is a value obtained by summing A of all combinations from the minimum value to the maximum value of each of the X coordinate and the Y coordinate.

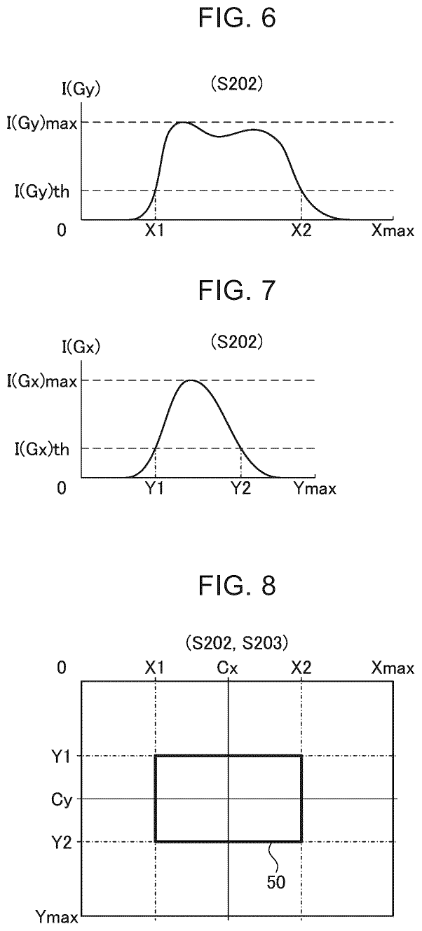

Referring back to FIG. 4, in S202, the processor 30 generates the outline 50 of the beam profile. An example of processing of generating the outline 50 will be described below with reference to FIGS. 6 to 8.

FIG. 6 is a graph showing an example of a distribution of a light intensity I(Gy) along a straight line in the X direction passing through the centroid position (Gx, Gy) in FIG. 5. In FIG. 6, the horizontal axis represents the X coordinate, and the vertical axis represents the light intensity I(Gy) at the position of Y=Gy. The maximum value of the light intensity I(Gy) is defined as I(Gy) max, and a value obtained by multiplying I(Gy) max by a coefficient greater than 0 and less than 1, for example, 1/e² is defined as a threshold value I(Gy)th. The value of X when the value of the light intensity I(Gy) first reaches the threshold value I(Gy)th as X is increased from the minimum value 0 is defined as X1. Further, the value of X when the value of the light intensity I(Gy) first reaches the threshold value I(Gy)th as X is decreased from the maximum value Xmax is defined as X2. X1 and X2 are not limited to integers, and a fraction may be obtained by interpolation calculation. The X direction corresponds to the first direction in the present disclosure.

FIG. 7 is a graph showing an example of distribution of a light intensity I(Gx) along a straight line in the Y direction passing through the centroid position (Gx, Gy) in FIG. 5. By replacing X with Y in the method described with reference to FIGS. 6, Y1 and Y2 are obtained. The Y direction corresponds to the second direction in the present disclosure.

FIG. 8 shows an example of the outline 50 defined by X1, X2, Y1, and Y2 obtained in FIGS. 6 and 7. The outline 50 has a rectangular shape. The outline 50 is generated so as to surround a portion of the beam profile having a light intensity equal to or higher than the threshold value I(Gy)th and a light intensity equal to or higher than the threshold value I(Gx)th.

The present disclosure is not limited thereto, and the outline 50 may be generated by performing edge detection on an image showing the beam profile. For example, by differentiating the distribution of the light intensity I(X, Y) in each of the X direction and the Y direction, the position where the absolute value of the gradient of brightness is equal to or greater than a threshold value can be detected as an edge. When the slits 16a, 16b, 26a, 26b, 36 are used, it is expected that a clear edge can be obtained. In this way, when the outline 50 is obtained without using the centroid position (Gx, Gy), S201 of FIG. 4 may be performed after S202 or S203.

In S203, the processor 30 calculates a center position (Cx, Cy) of the outline 50. After S203, the processor 30 ends processing of the present flowchart and returns to processing shown in FIG. 3.

As shown in FIG. 8 when the outline 50 is rotationally symmetrical, the center of a figure defined by the outline 50 may be obtained as the center of the outline 50. For example, from X1, X2, Y1, and Y2 obtained in FIGS. 6 and 7, the center position (Cx, Cy) is calculated by following expressions.

Cx=(X1+X2)/2

Cy=(Y1+Y2)/2

The centroid of the figure defined by the outline 50 may be obtained as the center of the outline 50. Accordingly, it is possible to obtain the center of the outline 50 even when the outline 50 is not rotationally symmetrical.

### 2.3 Calculation of Shifted Outline 51

FIG. 9 is a flowchart showing an example of processing of generating the shifted outline 51. The processing shown in FIG. 9 corresponds to a subroutine of S300 shown in FIG. 3.

In S301, the processor 30 calculates a shift of the centroid position (Gx, Gy) with respect to the center position (Cx, Cy) of the beam profile. For example, the X-direction component of the shift is Gx-Cx and the Y-direction component of the shift is Gy-Cy.

In S302, the processor 30 generates the shifted outline 51 by moving the outline 50 in accordance with the shift. After S302, the processor 30 ends processing of the present flowchart and returns to processing shown in FIG. 3.

FIG. 10 shows the shifted outline 51 generated by shifting the position of the outline 50 in accordance with the shift of the centroid with respect to the center of the beam profile. The shifted outline 51 is shifted in the X direction with respect to the outline 50 by Gx-Cx, and is shifted in the Y direction by Gy-Cy.

### 2.4 Displaying of Beam Profile and Shifted Outline 51

FIG. 11 is a flowchart showing an example of processing of starting displaying of the beam profile and the shifted outline 51. The processing shown in FIG. 11 corresponds to a subroutine of S400 shown in FIG. 3.

In S401, the processor 30 determines whether or not the shift of the centroid with respect to the center is within an allowable range. For example, it is determined whether or not the shift is equal to or less than a threshold value. When the shift is not within the allowable range (S401: NO), the processor 30 advances processing to S402. When the shift is within the allowable range (S401: YES), the processor 30 advances processing to S403.

In S402, the processor 30 generates an image signal including the beam profile and the shifted outline 51 and transmits the image signal to the display 33, so that displaying is started.

FIG. 12 shows a display example of the beam profile and the shifted outline 51. By displaying the shifted outline 51 on the image showing the beam profile in a superimposed manner, it is possible to show the shift of the centroid of the beam profile with respect to the center of the beam profile. In FIG. 12, the shift of the centroid with respect to the center is more clearly shown by further displaying the outline 50 of the beam profile. Here, there are cases in which the shift of the centroid with respect to the center can be sufficiently shown without displaying the outline 50, such as cases in which the slits 16a, 16b, 26a, 26b, 36 are used.

When both the outline 50 and the shifted outline 51 are displayed, it is desirable that the outline 50 and the shifted outline 51 are displayed in different display formats. The different display formats may be, for example, different thicknesses, different colors, different types of lines such as a solid line, a broken line, a dashed-dotted line, and a wave line, or different intervals of cut portions of broken lines. Further, it is desirable that the outline 50 and the shifted outline 51 have the same shape, the same size, and the same orientation. In a case in which the shifted outline 51 or both the outline 50 and the shifted outline 51 are rectangles whose long side extends in the X direction, the direction of the long side corresponds to the V direction.

Referring back to FIG. 11, in S403, the processor 30 generates an image signal including the beam profile, the shifted outline 51, and information indicating that the shift of the centroid with respect to the center is within the allowable range, and transmits the image signal to the display 33. The information indicating that the shift is within the allowable range may be indicated by a character such as “optical axis adjustment OK”, or may be indicated by a motion such as blinking or color change of the shifted outline 51. In addition to the displaying on the display 33, a sound such as “optical axis adjustment has been completed” may be output from a speaker (not shown). After S402 or S403, the processor 30 ends processing of the present flowchart and returns to processing shown in FIG. 3.

### 2.5 Effect

(1) According to the embodiment, the profile display device 34 includes the interface I/F that receives the beam profile of the laser light B2, the processor 30 that generates the shifted outline 51 by shifting the position of the outline 50 of the beam profile in accordance with the deviation of the light intensity distribution in the beam profile, and the display 33 that displays the beam profile and the shifted outline 51.

Even if one point of the centroid of the beam profile is displayed to show the deviation of the light intensity distribution in the beam profile, it may be too small to be seen. Further, since the centroid of the beam profile is located near the peak intensity or in a region of a low intensity between two peaks, when the centroid is displayed together with the beam profile, the contrast may be low and the display of the centroid may be difficult to be seen. According to the embodiment, by displaying the shifted outline 51, the deviation of the light intensity distribution can be displayed visually more clearly than by displaying one point of the centroid. In many cases, the vicinity of the outline 50 of the beam profile has a low intensity, and at least a part of the shifted outline 51 is shifted to the outside of the beam even when the outline 50 is shifted in any direction in the image. Therefore, for example, when the shifted outline 51 is displayed in a bright color, a display having a high contrast and being easy to see is obtained.

(2) According to the embodiment, the processor 30 generates the shifted outline 51 at regular intervals based on the beam profile newly received via the interface I/F. The display 33 updates the display of the beam profile and the shifted outline 51 every time the processor 30 generates the shifted outline 51.

Accordingly, since the beam profile and the shifted outline 51 are updated, it is possible to read how the shift has changed by the motion of the image.

(3) According to the embodiment, the outline 50 has a rectangular shape.

Accordingly, the outline 50 can be generated by a simple calculation. Further, when the rectangular outline 50 is displayed together with the rectangular shifted outline 51, the direction of the shift and the amount of the shift can be displayed in an easy-to-understand manner.

(4) According to the embodiment, the processor 30 generates the outline 50 so as to surround a portion of the beam profile having a light intensity equal to or higher than each of the threshold values I(Gy)th and I(Gx)th.

Accordingly, the outline 50 can be generated by a simple calculation.

(5) According to the embodiment, the processor 30 may generate the outline 50 by performing edge detection on the beam profile.

Accordingly, it is possible to generate the outline 50 faithful to the shape of the beam profile.

(6) According to the embodiment, the processor 30 generates the shifted outline 51 by shifting the position of the outline 50 in accordance with the shift of the centroid of the beam profile with respect to the center of the outline 50.

Accordingly, by performing displaying in accordance with the shift of the centroid with respect to the center, it is possible to obtain a guideline regarding which direction and what extent the optical axis adjustment should be performed in and to in order to eliminate the shift between the center and the centroid.

(7) According to the embodiment, the center of the outline 50 is the centroid of a figure defined by the outline 50.

Accordingly, even when the outline 50 has a complicated shape that is not rotationally symmetrical, the shift between the center and the centroid can be clearly defined and displayed.

(8) According to the embodiment, the processor 30 calculates the centroid position (Gx, Gy) by following expressions, where I(X, Y) is the light intensity at a point (X, Y) in the beam profile.

Gx=Σ(I(X,Y)×X)/Σ(I(X,Y))

Gy=Σ(I(X,Y)×Y)/Σ(I(X,Y))

Accordingly, the centroid position (Gx, Gy) can be accurately obtained from the two-dimensional distribution of the light intensity I(X, Y).

(9) According to the embodiment, the processor 30 calculates the center position Cx in the X direction from the distribution of the light intensity I(Gy) along the straight line in the X direction passing through the centroid position (Gx, Gy), and calculates the center position Cy in the Y direction from the distribution of the light intensity I(Gx) along the straight line in the Y direction passing through the centroid position (Gx, Gy) and intersecting the X direction.

Accordingly, by using the light intensity distributions along straight lines passing through the centroid position (Gx, Gy), the center position (Cx, Cy) can be obtained by simple calculation.

(10) According to the embodiment, the processor 30 determines whether or not the deviation of the light intensity distribution is within the allowable range, and the display 33 displays information indicating whether or not the deviation of the light intensity distribution is within the allowable range in accordance with the determination by the processor 30.

When the shift between the center and the centroid is eliminated by the optical axis adjustment, the shifted outline 51 may overlap with the original outline 50 and become difficult to be seen. However, according to the embodiment, it is possible to perceive that the shift is eliminated by displaying the information indicating whether or not the deviation of the light intensity distribution is within the allowable range.

(11) According to the embodiment, the display 33 further displays the outline 50.

Accordingly, even when the outer shape of the beam profile is not clear, the shift of the shifted outline 51 can be clearly recognized by displaying the outline 50.

(12) According to the embodiment, the display 33 displays the outline 50 and the shifted outline 51 in different display formats.

Accordingly, it is clear which of the outline 50 and the shifted outline 51 is the shifted outline 51, so that the direction in which the centroid is shifted can be clearly recognized.

(13) According to the embodiment, the outline 50 and the shifted outline 51 have the same shape and the same size.

Accordingly, the positional shift between the center and the centroid can be clearly displayed by setting both the shape and the size to be the same.

(14) According to the embodiment, the laser device 100 includes the laser oscillator 1 that outputs the laser light B2, the beam profiler 32 that acquires the beam profile of the laser light B2, the processor 30 that generates the shifted outline 51 by shifting the position of the outline 50 of the beam profile in accordance with the deviation of the light intensity distribution in the beam profile, and the display 33 that displays the beam profile and the shifted outline 51.

Accordingly, by displaying the shifted outline 51, the deviation of the light intensity distribution can be displayed visually more clearly than by displaying one point of the centroid. In many cases, the vicinity of the outline 50 of the beam profile has a low intensity, and at least a part of the shifted outline 51 is shifted to the outside of the beam even when the outline 50 is shifted in any direction in the image. Therefore, for example, when the shifted outline 51 is displayed in a bright color, a display having a high contrast and being easy to see is obtained.

(15) According to the embodiment, the laser device 100 further includes the slit 36 arranged on the optical path of the laser light B2 output from the laser oscillator 1.

Accordingly, since the outer shape of the beam profile becomes clear, the positional relationship between the outline 50 and the shifted outline 51 can be easily grasped even when the outline 50 is not displayed.

(16) According to the embodiment, the laser device 100 further includes the optical axis adjustment mechanisms 14a, 15a, 24a, 25a, 41a, 42a configured to be capable of adjusting the postures of the optical elements included in the laser oscillator 1. The display 33 updates the display of the shifted outline 51 when the beam profile is changed with the operation of the optical axis adjustment mechanisms 14a, 15a, 24a, 25a, 41a, 42a.

Accordingly, since the shifted outline 51 is updated when the optical axis adjustment mechanisms 14a, 15a, 24a, 25a, 41a, 42a are operated, it is possible to perceive how the operation of the optical axis adjustment mechanisms 14a, 15a, 24a, 25a, 41a, 42a affects the change of the beam profile, and thus the optical axis adjustment can be efficiently performed.

(17) According to the embodiment, the laser oscillator 1 includes the laser chambers 10, 20 accommodating the laser gas, the discharge electrodes 11a, 11b arranged in the laser chamber 10, and the discharge electrodes 21a, 21b arranged in the laser chamber 20. The outline 50 has a rectangular shape, and the X direction, which is the direction of the long side of the rectangular shape, corresponds to the V direction, which is the direction of discharge caused by the discharge electrodes 11a, 11b, 21a, 21b.

Accordingly, the direction of the shift of the shifted outline 51 can be recognized with reference to the X direction, which is the direction of the long side of the outline 50, and the optical axis adjustment can be performed with reference to the V direction, which is the direction of the discharge. Therefore, by making the X direction and the V direction to correspond to each other, the outline 50 and the shifted outline 51 can be easily matched by the optical axis adjustment.

(18) According to the embodiment, the optical axis adjustment mechanisms 14a, 15a, 24a, 25a, 41a, 42a are capable of adjusting the postures of the optical elements in parallel with outputting of a plurality of pulses of the laser light B2 by the laser oscillator 1.

Accordingly, since the optical axis can be adjusted while outputting the laser light B2, the beam profile after the optical axis is adjusted can be acquired quickly.

(19) According to the embodiment, the processor 30 determines whether or not the deviation of the light intensity distribution is within the allowable range, and the display 33 displays information indicating whether or not the deviation of the light intensity distribution is in accordance with the within the allowable range determination by the processor 30.

Accordingly, when the deviation of the light intensity distribution becomes within the allowable range as a result of operation of the optical axis adjustment mechanisms 14a, 15a, 24a, 25a, 41a, 42a, adjustment completion of the optical axis can be perceived. In other respects, the embodiment is similar to the comparative example.

### 3. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A profile display device comprising:
an interface configured to receive a beam profile of laser light;
a processor configured to generate a shifted outline by shifting a position of an outline of the beam profile in accordance with deviation of a light intensity distribution in the beam profile; and
a display configured to display the beam profile and the shifted outline.

2. The profile display device according to claim 1,
wherein the processor generates the shifted outline at regular intervals based on the beam profile newly received via the interface, and
the display updates display of the beam profile and the shifted outline every time the processor generates the shifted outline.

3. The profile display device according to claim 1,
wherein the outline has a rectangular shape.

4. The profile display device according to claim 1,
wherein the processor generates the outline so as to surround a portion of the beam profile having a light intensity equal to or higher than a threshold value.

5. The profile display device according to claim 1,
wherein the processor generates the outline by performing edge detection on the beam profile.

6. The profile display device according to claim 1,
wherein the processor generates the shifted outline by shifting the position of the outline in accordance with a shift of a centroid of the beam profile with respect to a center of the outline.

7. The profile display device according to claim 6,
wherein the center is a centroid of a figure defined by the outline.

8. The profile display device according to claim 6,
wherein the processor calculates a position of the centroid (Gx, Gy) by following expressions,
Gx=Σ(I(X,Y)×X)/Σ(I(X,Y))
Gy=Σ(I(X,Y)×Y)/Σ(I(X,Y))
where I(X,Y) is a light intensity at a point (X,Y) in the beam profile.

9. The profile display device according to claim 8,
wherein the processor calculates a position of the center Cx in a first direction from a distribution of a light intensity I(Gy) along a straight line in the first direction passing through the position of the centroid (Gx, Gy), and calculates a position of the center Cy in a second direction from a distribution of a light intensity I(Gx) along a straight line in the second direction passing through the position the centroid of (Gx, Gy) and intersecting the first direction.

10. The profile display device according to claim 1,
wherein the processor determines whether or not the deviation of the light intensity distribution is within an allowable range, and
the display displays information indicating whether or not the deviation of the light intensity distribution is within the allowable range in accordance with the determination by the processor.

11. The profile display device according to claim 1,
wherein the display further displays the outline.

12. The profile display device according to claim 11,
wherein the display displays the outline and the shifted outline in different display formats.

13. The profile display device according to claim 11,
wherein the outline and the shifted outline have the same shape and the same size.

14. A laser device comprising:
a laser oscillator configured to output laser light;
a beam profiler configured to acquire a beam profile of the laser light;
a processor configured to generate a shifted outline by shifting a position of an outline of the beam profile in accordance with deviation of a light intensity distribution in the beam profile; and
a display configured to display the beam profile and the shifted outline.

15. The laser device according to claim 14, further comprising:
a slit arranged on an optical path of the laser light output from the laser oscillator.

16. The laser device according to claim 14, further comprising:
an optical axis adjustment mechanism configured to be capable of adjusting a posture of an optical element included in the laser oscillator,
wherein the display updates display of the shifted outline when the beam profile is changed with operation of the optical axis adjustment mechanism.

17. The laser device according to claim 16,
wherein the laser oscillator includes a laser chamber accommodating a laser gas and a pair of discharge electrodes arranged in the laser chamber, and
the outline has a rectangular shape, and a direction of a long side of the rectangular shape corresponds to a direction of discharge caused by the discharge electrodes.

18. The laser device according to claim 16,
wherein the optical axis adjustment mechanism is capable of adjusting the posture of the optical element in parallel with outputting of a plurality of pulses of the laser light by the laser oscillator.

19. The laser device according to claim 16,
wherein the processor determines whether or not the deviation of the light intensity distribution is within an allowable range, and
the display displays information indicating whether or not the deviation of the light intensity distribution is within the allowable range in accordance with the determination by the processor.

20. An electronic device manufacturing method, comprising:
generating laser light using a laser device;
outputting the laser light to an exposure apparatus; and
exposing a photosensitive substrate to the laser light in the exposure apparatus to manufacture an electronic device,
the laser device including:
a laser oscillator configured to output the laser light;
a beam profiler configured to acquire a beam profile of the laser light;
a processor configured to generate a shifted outline by shifting a position of an outline of the beam profile in accordance with deviation of a light intensity distribution in the beam profile; and
a display configured to display the beam profile and the shifted outline.
